(19) United States
(12) Patent Application Publication
(10) Pub. No.: US 2002/0015901 A1
(43) Pub. Date: Feb. 7, 2002

(54) Photosensitive solution for forming picture cell and color filter produced by using the same

(76) Inventors: Kazuo Takebe, Osaka (JP); Toshiya Inoue, Osaka (JP); Kiyoharu Nakatsuka, Osaka (JP)

Correspondence Address: Stevens, Davis, Miller & Mosher, L.L.P., Suite 850, 1615 L Street, N.W., Washington, DC, 20036, US

(21) Appl. No.: 09/891,462

(22) Filed: Jun. 27, 2001

(30) Foreign Application Priority Data
Jun. 28, 2000 (JP) 2000-194271

(51) Int. Cl. G02B 5/20; G02F 1/1335; G03F 7/004

(52) U.S. Cl. 430/7; 430/270.1

(57) ABSTRACT

A photosensitive solution for forming a picture cell comprising a pigment [A], a binder polymer [B], a radiation-sensitive compound [C], a solvent [D] and a carboxylic acid or salts thereof [E], wherein the pigment [A] includes at least one selected from C. I. Pigment Red 242 and C. I. Pigment Red 254, and the carboxylic acid or salts thereof [E] include at least one selected from oxalic acid, malonic acid, succinic acid and salts thereof is provided, and, by using the photosensitive solution, colored picture cells having excellent adherence with a substrate can be uniformly formed without unevenness, while leaving no un-dissolved substance onto non-cell parts on a substrate.

### BACKGROUND OF THE INVENTION

The present invention relates to a photosensitive solution for forming a picture cell More particularly, it relates to a photosensitive solution for forming a picture cell that comprises a specific red pigment and specific dicarboxylic acids

Conventionally, a photosensitive solution is used for forming picture cells of a color filter used in a color liquid crystal display apparatus, image pick-up tube and the like. For example, picture cells are formed by applying a photosensitive solution on the surface of a substrate, and drying the solution to form a photosensitive coated film, then, exposing to light and developing the coated film. However, residues (un-dissolved substances), which was un-dissolved by the developer, may remain on a part of the surface of a substrate where a colored picture cell is not to be formed (hereinafter, this part is expresses by “non-cell part”.). In this case, the resulting color filter gets lowered transmission and has decreased contrast.

In a color filter, three color picture cells are usually formed sequentially on a substrate by using photosensitive solutions having red, blue and green hues respectively. However, when undissolved substances remain at the non-cell part on the surface of a substrate in forming a certain color picture cell, display failure occurs in forming a liquid crystal display element.

For preventing remaining of such un-dissolved substances, a carboxylic acid having a molecular weight of 1000 or less is added to such a photosensitive solution. As the carboxylic acid, a lot of carboxylic acids are exemplified such as formic acid, acetic acid, maleic acid, oxalic acid and the like (JP-A Nos. 5-343631 and 11-231516) However, when red pigments, C. I. Pigment Red 242 and C. T. Pigment Red 254 are used as the pigment, there is a problem that un-dissolved substances remain even if carboxylic acids having a molecular weight of 1000 or less, such as formic acid and acetic acid, maleic acid are used.

The present inventors have intensively studied carboxylic acids to prevent remaining of un-dissolved substances at non-cell parts on a substrate when red pigments, C. I. Pigment Red 242 and C. I. Pigment Red 254 are used as the pigment. As the result, they have found that, by using a such specific carboxylic acids as oxalic acid, malonic acid and succinic acid and/or salts thereof as the carboxylic acids, remaining of un-dissolved substances at non-cell parts on a substrate can be prevented, and colored picture cells excellent in adherence with a substrate can be formed uniformly Thus, the present invention was completed.

### SUMMARY OF THE INVENTION

Namely, the present invention provides a practically excellent photosensitive solution for forming a picture cell comprising a pigment [A], a binder polymer [B], a radiation-sensitive compound [C], a solvent [D] and a carboxylic acid or salts thereof [E], wherein the pigment [A] includes at least one selected from C. I. Pigment Red 242 and C. I. Pigment Red 254, and the carboxylic acid or salts thereof [E] include at least one selected from oxalic acid, malonic acid, succinic acid and salts thereof. Hereinafter, the expression, “the carboxylic acid” or “the carboxylic acid [E]”, indicates at least one selected from oxalic acid, malonic acid, succinic acid and salts thereof.

The photosensitive solution for forming a picture cell of the present invention may optionally comprise a pigment other than C. I. Pigment Red 242 and C. I. Pigment Red 254, and another additive in addition to the above mentioned essential components [A ], [B], [C], [D] and [E]. Hereinafter, an expression, “the other pigment”, indicates the pigment other than C. I. Pigment Red 242 and C. I. Pigment Red 254.

### DETAILED DESCRIPTION OF THE PREFERRED EMBODIMENTS

In the photosensitive solution for forming a picture cell of the present invention, the pigment [A] includes at least one selected from C I. Pigment Red 242 and C. I. Pigment Red 254.

Total amount of C. I. Pigment Red 242, C. I. Pigment Red 254 and the other pigment is usually from 5 to 60% by weight, preferably from 10 to 50% by weight based on the total amount of all solid components in a photosensitive solution. Amount of the other pigments usually 50% by weight or less, preferably 40% by weight or less based on the total amount of pigments.

The binder polymer [B] makes the unexposed part of the coated film alkali soluble and acts as a dispersing medium for a pigment. The binder polymer [B] can be selected from various polymers used in this field. This binder polymer is preferably a copolymer having a carboxyl group. As the copolymer having a carboxyl group, particularly, copolymers obtained from a carboxyl group-containing monomer and other monomer copolymerizable therewith are preferably used.

The carboxyl group-containing monomer can be, for example, an unsaturated carboxylc acid having at least one carboxyl group in the molecule, such as an unsaturated monocarboxylic acid and unsaturated dicarboxylic acid. Specific examples thereof include acrylic acid, methacrylic acid, crotonic acid, itaconic acid, maleic acid and fumaric acid. These carboxyl group-containing monomers can be used each alone or in combination of two or more. The monomer copolymerizable with such carboxyl group-containing monomers is a compound having a polymerizable carbon-carbon unsaturated bond. Specific examples thereof include aromatic vinyl compounds such as α-methylstyrene vinyltoluene and the like, unsaturated carboxylates such as methyl (meth)acrylate, ethyl (meth)acrylate, butyl (meth)acrylate, 2-hydroxylethyl (meth)acrylate, benzyl (meth)acrylate and the like, unsaturated aminoalkyl carboxylates such as aminoethyl acrylate and the like, unsaturated glycidyl carboxylates such as glycidyl (meth)acrylate and the like, vinyl carboxylates such as vinyl acetate and vinyl propionate and the like, vinyl cyanide compounds such as (meth)acrylonitrile and α-chloroacryloitrile, and the like. These monomers can also be used each alone or in combination of two or more. In this copolymer, the carboxyl group-containing monomer is used in an amount of preferably from 10 to 50% by weight, more preferably from 15 to 40% by weight based on the total amount of monomers.

Preferable specific examples of such copolymer having a carboxyl group include benzyl methacrylate/methacrylic acid copolymer, benzyl methacrylate/methacrylic acid/styrene copolymer, methyl methacrylate/methacrylic acid copolymer, methyl methacrylate/methacrylic acid/styrene copolymer and the like. These copolymers having a carboxyl group preferably have weight-average molecular weight measured by gel permeation chromatography converted to polystyrene of from 5000 to 400000, more preferably from 10000 to 300000. The binder resin is used in an amount of usually from 5 to 90% by weight, preferably from 20 to 70% by weight based on the total amount of all solid components (that is, amount of photosensitive solution excepting amount of solvent) in the photosensitive solution.

As the radiation-sensitive compound [C], mixtures of a photopolymerization initiator and a compound polymerizable by the action of light and the photopolymerization initiator can be mentioned In general, the latter have a polymerizable carbon-carbon unsaturated bond, and can be a bi-functional, or other poly-functional monomer as well as a mono-functional monomer. Specific examples of the mono-functional monomer include nonylphenylcarbitol acrylate, 2-hydroxy-3-phenoxypropyl acrylate, 2-ethylhexylcarbitol acrylate, 2-hydroxyethylacrylate, N-vinylpyrrolidone and the like. Specific examples of the bi-functional monomer include 1,6-hexanediol di(meth)acrylate, ethylene glycol di(meth)acrylate, neopentyl glycol di(meth)acrylate, triethylene glycol di(meth)acrylate, bis(acryloyloxyethyl) ether of bisphenol A, 3-methylpentanediol di(meth)acrylate and the like. Examples of the other poly-functional monomer include trimethylolpropane tri(meth)acrylate, pentaerythritol tri(meth)acrylate, pentaerythritol tetra(meth)acrylate, dipentaerythrltol penta(meth)acrylate, dipentaerythritol hexa(meth)acrylate and the like.

These monomers can be used each alone or in combination of two or more. It is preferred that at least one bi- unctional or other poly-functional monomer is used. The amount of them is generally from 0.1 to 60 parts by weights preferably from 1 to 30 parts by weight based on 100 parts by weight of the total amount of a binder resin and photopolymerizable monomers

Photopolymerization initiator usually used in this field can be used in the present invention. Examples thereof include acetophenone-based initiators, benzoin-based initiators, benzophenone-based initiators, thioxanetone-based initiators, triazine-based initiators and other initiators. Specific examples of the acetophenone-based initiator include oligomers of diethoxyacetophenone,

2-hydroxy-2-methyl-1-phenylpropane-1-one, benzyldlmethylketal,

2-hydroxy-2-methyl-l-[4-(2-hydroxyethoxy)phenyl]propane-1-one, 1-hydroxycyclohexylphenylketone,

2-methyl-2-morpholino-1-(4methylthiophenyl)propane-1-one,

2-benzyl-2-dimethylamino-1-(4-morpholinophenyl)butane-1-o ne and

2-hydroxy-2-methyl-1-[4-(1-methylvinyl)phenyllpropane-1-o ne, and the like. Specific examples of the benzoin-based initiators include benzoin, benzoin methyl ether, benzoin ethyl ether, benzoin isopropyl ether, benzoin isobutyl ether and the like. Specific examples of the benzophenone-based initiator include benzophenone, methyl o-benzoylbenzoate,

4-phenylbenzophenone, 4-benzoyl-4′-methyldiphenylsulfide,

3,3′,4,4′-tetra(tert-butylperoxycarbonyl)benzophenone,

2,4,6-trimethylbenzophenoneandthelike. Specificexamples of the thioxanetone-based initiator include 2-isopropylthioxanetone, 4-isopropylthioxanetone, 2,4-diethylthioxanetone, 2,4-dichlorothioxanetone, 1-chloro-4-propoxythloxanetone and the like.

Specific examples of the triazine-based initiator include

2,4-bis(trichloromethyl)-6-(4-methoxyphenyl)-1,3,5-triazi ne,

2,4-bis(trichloromethyl)-6-(4-methoxynaphthyl)-1,3,5-tria zine, 2,4-bi s(trichloromethyl )-6-piperonyl- 1,3, 5-triazine,

2,4-bis(trichloromethyl)-6-(4-methoxystyryl)-1,3,5-triazl ne,

2,4-bis(trichloromethyl)-6-[2-(5-methylfuran-2-yl)ethenyl]-1,3,5-triazine,

2.4-bis(trichloromethyl)-6-[2-(furan-2-yl)ethenyl]-1,3,5-triazine,

2,4-bis(trichloromethyl)-6-[2-(4-diethylamino-2-methylphe nyl)ethenyl]-1,3,5-triazlne,

2,4-bis(trichloromethyl)-6-[2-(3,4-dimethoxyphenyl)etheny 1]-1,3,5-triazine and the like. Specific examples of the other initiator include

2,4,6-trimuethylbenzoyldiphenylphosphine oxide,

2,2′-bis(o-chlorophenyl)-4,4′, 5,5′-tetraphenyl-1,2′-biimi dazole, 10-butyl-2-chloroacridone, 2-ethylanthraquinone, benzil, 9,10-phenanethrenequinone, camphorquinone, methyl phenylglyoxylate, titanocene compounds and the like. These photopolymerization initiators can be used each alone or in combination of two or more.

A photopolymerlzation aid can also be combined with a photopolymerization initiator. As the photopolymerization aid, for example, amine-based aids and alkoxyanthracene-based aids are listed. Specific examples thereof include triethanolamine, methyldiethanolamine, truisopropanolamine, methyl 4-dimethylaminobenzoate, ethyl 4-dimethylaminobenzoate, isoamyl 4-dimethylaminobenzoate, 2-dimethylaminoethyl benzoate, 2-ethylhexyl 4-dimethylaminobenzoate, N,N-dimethylparatoluidine, 4,4′-bis(dimethylamino)benzophenone (commonly called Michler's ketone), 4,4′-bis(diethylamino)benzophenone, 9,10-dimethoxyanthracene, 2-ethyl-9,10 -dmethoxyanthracene, 9,10-diethoxyanthracene, 2-ethyl-9,10-diethoxyanthracene and the like. These photopolymerization aids can also be used each alone or in combination of two or more.

Total amount of the photopolymerization initiator and the photopolymerization aid, If any, is generally from 3 to 30 parts by weight, preferably from 5 to 25 parts by weight based on 100 parts by weight of the total amount of a binder polymer, and compounds polymerizable by the action of light and a photopolymerization initiator.

The solvent [D] used In the present invention can be selected from various solvents known in this field. Specific examples thereof include ethylene glycol monoalkyl ethers such as ethylene glycol monomethyl ether, ethylene glycolmonoethyl ether, ethylene glycol monopropyl ether and ethylene glycol monobutyl ether; diethylene glycol dialkyl ethers such as diethylene glycol dimethyl ether, diethylene glycol diethyl ether, diethylene glycol dipropyl ether and diethylene glycol dibutyl ether; ethylene glycol alkyl ether acetates such as methylcellosolve acetate and ethylcellosolve acetate, alkylene glycol alkyl ether acetates such as propylene glycol monomethyl ether acetate, propylene glycol monoethyl ether acetate, propylene glycol monopropyl ether acetate, methoxybutyl acetate and methoxypentyl acetate; aromatic hydrocarbons such as benzene, toluene and xylene; ketones such as methyl ethyl ketone, acetone, methyl amyl ketone, methyl isobutyl ketone and cyclohexanone; alcohols such as ethanol, propanol, butanol, hexanol, cyclohexanol, ethylene glycol and glycerine; esters such as ethyl 3-ethoxypropionate and methyl 3-methoxyproplonate; cyclic esters such as γ-butyrolactone; and the like. These solvents can be used each alone or in combination of two or more. The amount of the solvent used is preferably from 50 to 90% by weight, more preferably from 60 to 85% by weight based on the amount of the whole photosensitive solution including the solvent.

The present invention is characterized in that at least one selected from oxalic acid, malonic acid, succinic acid and salts thereof is used, as the carboxylic acid [E]. As the salt, alkali metals salts, ammonium salts and amine salts of the above-mentioned acids or mixtures thereof are exemplified. Among them, ammonium salts, amine salts and mixtures thereof are preferred.

The carboxylic acid [E] is added to the photosensitive solution of the present invention in an amount of usually from 0.001 to 10% by weight, preferably from 0.05 to 5% by weight based on the total amount of all solid components in a photosensitive solution. When the amount is less than 0.001% by weight, remaining of undissolved substances onto non-cell parts on a substrate can not be sufficiently prevented, on the other hand, when the amount exceeds 10% by weight, adherence between picture cells and a substrate tends to lower.

The radiation-sensitive composition for color filter of the present invention may also contain additives, if necessary. Specific examples of such additives include fillers, other polymer compounds, surfactants, adherence promoters, antioxidants, ultraviolet absorbers, coagulation preventing agents and the like.

More specific examples thereof include fillers such as glass, alumina and the like; other polymer compounds such as polyvinyl alcohol, polyacrylic acid, polyethylene glycol monoalkyl ether, polyfluoroalkyl acrylate and the like;

nonionic, cationic and anionic surfactants; adherence promoters such as vinyltrimethoxysilane,

vinyltriethoxysilane, vinyltris (2-methoxyethoxy) silane,

N- (2-aminoethyl) -3-aminopropylmethyldimethoxysilane,

N-(2-aminoethyl)-3-aminopropyltrimethoxysilane,

3-aminopropyltriethoxysilane,

3-glycidoxypropyltrimethoxysilane,

3-glycidoxypropylmethyldimethoxysilane,

2-(3,4-epoxycyclohexy)ethyltrimethoxysilane,

3-chloropropylmethyldimethoxysilane,

3-chloropropyltrimethoxysilane,

3-methacryloxypropyltrimethoxysllane,

3-mercaptopropyltrimethoxysilane and the like; antioxidants such as 2,2-thiobis(4-methyl-6-t-butylphenol),

2, 6-di-t-butylphenol and the like; ultraviolet absorbers such as

2-(3-t-butyl-5-methyl-2-hydroxyphenyl)-5-chlorobenzotriaz ole, alkoxybenzophenone and the like; and coagulation preventing agents such as sodium polyacrylate.

By using thus obtained photosensitive solution for forming a picture cell of the present invention, a color filter can be produced without remaining un-dissolved substances at non-cell parts on the surface of a substrate in developing.

In the production of a color filter, colored picture cells can be formed by a photolithography methodona substrate, preferably on a substrate on which shielding layer patterns were formed in forming picture cells by such a photolithography method, if the photosensitive solution of the present invention is used, un-dissolved substances do not remain on non-cell parts. As the result, theo formed colored picture cells, namely, a color filter manifests excellent adherence with a substrate and shieding layer patterns, and additionally, does not cause possibility of display failure in forming a liquid crystal display element. Therefore, picture cells formed by using the photosensitive solution of the present invention gives no fear of peeling from a substrate, and the resulted color filter has excellent transmittance and contrast.

As described above, when the photosensitive solution for producing color filter of the present invention is used, a color filter having high performances can be produced in excellent yield. As a developer used in forming picture cells in the present invention, an alkaline solution such as sodium carbonate, sodium hydroxide, potassium hydroxide, potassium carbonate, tetramethylammonium hydroxide or the like are preferred.

The following examples illustrate the present invention more specifically. They do not restrict the scope of the present invention. In the examples, “parts” is weight basis unless otherwise stated.

### EXAMPLE 1

On the surface of a glass substrate (Corning, #7059), a shielding layer having desired patterns was formed. A photosensitive solution 1 as shown in Table 1 was applied on the substrate thus formed by a spin coater to provide given thickness, then, the layer was dried at 100° C. for 3 minutes. Then, after cooling, the formed colored layer was exposed to ultraviolet ray of 150 mj/cm² by an extra high pressure mercury lamp through a photo mask. Thereafter, this substrate was immersed in an aqueous solution containing 0.05% potassium hydroxide and 0.2% sodium butylnaphthalenesulfonate for causing development, to form red picture cells.

On the resulting color filter, remaining of un-dissolved substances was not recognized at non-cell parts on the substrate (including on chromium layer).

TABLE 1

| | | | |
|---|---|---|---|
| Pigment | C. I. Pigment Red 242 | 4.53 | parts |
| Binder | Benzyl methacrylate/methacrylic | 4.94 | parts |
| polymer | acid copolymer | | |
| | (weight formulation 80/20, | | |
| | weight-average molecular weight | | |
| | 35,000) | | |
| Monomer | Dipentaerythritol hexaacrylate | 4.85 | parts |
| | (Manufactured by Nippon Kayaku | | |
| | Co., Ltd., “KAYARAD DPHA”) | | |
| Photopoly- | Irgacure-907 (manufactured by | 1.17 | parts |
| merization | CIBA-GEIGY) | | |
| initiator | KAYACURE DETX-S (manufactured by | 0.58 | parts |
| | Nippon Kayaku Co., Ltd.) | | |
| Additive | pigment dispersing agent | 2.04 | parts |
| Solvent | propylene glycol monomethyl ether | 81.69 | parts |
| | acetate | | |
| Carboxylic | malonic acid/oxalic acid (=1/1) | 0.2 | parts |
| acids | | | |

### Comparative Example 1

Red picture cells were formed according to the same manner as in Example 1 except that a photosensitive solution 2 was used which was obtained by using 81.89 parts of propylene glycol monomethyl ether acetate instead of 81.69 parts of propylene glycol monomethyl ether acetate and 0.20 parts of malonic acid and oxalic acid in Example 1.

On the resulting color filter, remaining of un-dissolved substances was recognized on non-cell parts on the substrate.

### EXAMPLE 2

Red picture cells were formed according to the same manner as in Example 1 except that a photosensitive solution 3 shown in Table 2 was used instead of the photosensitive solution 1 used in Example 1.

On the resulting color filter, remaining of un-dissolved substances was not recognized at non-cell parts on the substrate (including on chromium layer).

TABLE 2

| | | | |
|---|---|---|---|
| Pigment | C. I. Pigment Red 254 | 5 | parts |
| Binder | Benzyl methacrylate/methacrylic | 5.72 | parts |
| polymer | acid copolymer | | |
| | (weight formulation 80/20, | | |
| | weight-average molecular weight | | |
| | 35,000) | | |
| Monomer | Dipentaerythritol hexaacrylate | 5.72 | parts |
| | (Manufactured by Nippon Kayaku | | |
| | Co., Ltd., “KAYARAD DPHA”) | | |
| Photopoly- | Irgacure-907 (manufactured by | 1.37 | parts |
| merization | CIBA-GEIGY) | | |
| initiator | KAYACURE DETX-S (manufactured by | 0.69 | parts |
| | Nippon Kayaku Co., Ltd.) | | |
| Additive | pigment dispersing agent | 1.5 | parts |
| Solvent | propylene glycol monomethyl ether | 79.8 | parts |
| | acetate | | |
| Carboxylic | malonic acid | 0.2 | parts |
| acids | | | |

### EXAMPLE 3

Red picture cells were formed according to the same manner as in Example 1 except that a photosensitive solution which had the same composition as the photosensitive solution 3 shown in Table 2, but had been left as it had been for 1 week at 23° C. was used instead of the photosensitive solution 1 used in Example 1.

On the resulting color filter, remaining of un-dissolved substances was not recognized at non-cell parts on the substrate.

### EXAMPLE 4

Red picture cells were formed according to the same manner as in Example 2 except that a photosensitive solution 4 which had the same compositlon as the photosensitive solution 3 shown in Table 2, but malonic acid was replaced with succinic acid was used instead of the photosensitive solution 3 used in Example 2.

On the resulting color filter, remaining of un-dissolved substances was not recognized at non-cell parts on the substrate.

### Comparative Example 2

Red picture cells were formed according to the same manner as in Example 2 except that a photosensitive solution 5 which had the same composition as the photosensitive solution 3 shown in Table 2, but 79.8 parts of propylene glycol monomethyl ether acetate and 0.2 parts of malonic acid were replaced with 80 parts of propylene glycol monomethyl ether acetate was used instead of the photosensitive solution 3 used in Example 2.

On the resulting color filter, remaining of un-dissolved substances was recognized on non-cell parts on the substrate.

### Comparative Examples 3-9

Red picture cells were formed according to the same manner as in Example 2 except that each of photosensitive solutions 6-12 which had the same composition as the photosensitive solution 3 shown in Table 2, but 0.2 parts of malonic acid were replaced with 0.2 parts of acetic acid, 0.2 parts of lauric acid, 0.2 parts of formic acid, 0.2 parts of glutaric acids 0.2 parts of adipic acid, 0.2 parts of maleic acid or 0.2 parts of benzoic acid, respectively.

On the resulting color filter, remaining of un-dissolved substances was recognized on non-cell parts on the substrate.

### Reference Example

Red picture cells were formed according to the same manner as in Example 2 except that a photosensitive solution 13 which had the same composition as the photosensitive solution 3 shown in Table 2, but C. I. Pigment Red 254 was replaced with C. I. Pigment Green 36 was used instead of the photosensitive solution 3 used in Example 2.

On the resulting color filter, remaining of un-dissolved substances was recognized on non-cell parts on the substrate.

When picture cells are formed by using the photosensitive solution of the present invention, colored picture cells having excellent adherence with a substrate can be uniformly formed without unevenness, while leaving no un-dissolved substance onto non-cell parts on a substrate.

Therefore, colored picture cells formed by using the photosensitive solution of the present invention do not cause possibility of peeing from a substrate, and the resulted color filter has excellent transmittance or contrast. When it is used as a liquid crystal display element, there is no fear of display failure.

What is claimed is:

1. A photosensitive solution for forming a picture cell comprising a pigment [A], a binder polymer [B], a radiation-sensitive compound [C], a solvent [D] and a carboxylic acid or salts thereof [E], wherein the pigment [A] includes at least one selected from C. I. Pigment Red 242 and C. I. Pigment Red 254, and the carboxylic acid or salts thereof [E] include at least one selected from oxalic acid, malonic acid, succinic acid and salts thereof.

2. The photosensitive solution according to claim 1, wherein the amount of the carboxylic acid or salts thereof [E] is from 0.001 to 10% by weight, based on the total amount of all solid components in a photosensitive solution.

3. The photosensitive solution according to claim 2, wherein the binder polymer [B] is a copolymer having a carboxyl group.

4. The photosensitive solution according to claim 2, wherein the radiation-sensitive compound [C] is a mixture of a photopolymerization initiator and a compound polymerizable by the action of light and the photopolymerization initiator.

5. A color filter which has red picture cells produced by using photosensitive solution comprising a pigment (A], a binder polymer [B], a radiation-sensitive compound [C], a solvent [D] and a carboxylic acid or salts thereof [E], wherein the pigment [A] includes at least one selected from C. I. Pigment Red 242 and C. I. Pigment Red 254, and the carboxylic acid or salts thereof [E] include at least one selected from oxalic acid, malonic acid, succinic acid and salts thereof.
